(19) United States
(12) Patent Application Publication
(10) Pub. No.: US 2019/0169744 A1
(43) Pub. Date: Jun. 6, 2019

(54) SUBSTRATE TREATMENT APPARATUS

(71) Applicant: MEYER BURGER (GERMANY) GMBH, Hohenstein-Ernsthal (DE)

(72) Inventors: Sebastian RASCHKE, Thalheim (DE); Erik ANSORGE, Chemnitz (DE); Mirko KEHR, Amtsberg (DE); Christian BOEHM, Hohenstein-Ernstthal (DE)

(73) Assignee: Meyer Burger (Germany) GmbH, Hohenstein-Ernsthal (DE)

(21) Appl. No.: 15/754,943

(22) PCT Filed: Aug. 2, 2016
(86) PCT No.: PCT/IB2016/054632

§ 371 Date: Feb. 23, 2018

(30) Foreign Application Priority Data
Aug. 24, 2015 (DE) 10 2015 113 962.6

(51) Int. Cl. C23C 16/458; C23C 16/46; H01L 21/67; C23C 14/50

(52) U.S. Cl. CPC C23C 16/4581; C23C 16/463; C23C 14/50; C23C 16/4582; H01L 21/67109

(57) ABSTRACT

A substrate treatment apparatus for treating substrates has a plate-shaped substrate carrier and at least one plate-shaped tempering device, which is arranged parallel to the substrate carrier. The substrate carrier has a substrate carrier front side for supporting at least one laminar substrate and a substrate carrier back side, which faces the tempering device. The object of the present invention is to provide a substrate treatment apparatus which enables a heat distribution as evenly as possible in the substrate carrier. For that purpose, there is provided at least one spacer element for forming a distance between the substrate carrier and the tempering device at the substrate carrier back side and/or a surface of the tempering device facing the substrate carrier.

The present invention relates to a substrate treatment apparatus for treating substrates by means of a plate-shaped substrate carrier and at least one plate-shaped tempering device, which is arranged parallel to the substrate carrier, wherein the substrate carrier comprises a substrate carrier front side for supporting at least one laminar substrate and a substrate carrier back side, which faces the tempering device.

Such a substrate treatment apparatus is for example known from the document DE 10 2010 000 001 A1. In it, a laminar semiconductor substrate, such as a silicon wafer, is moved on a plate-shaped substrate carrier through a processing chamber, in order to deposit for example a passivation layer on the semiconductor substrate. For this purpose, the semiconductor substrate is placed on a front side of the substrate carrier, whereas at least one plate-shaped heating and/or cooling device is arranged facing the back side of the substrate carrier.

With such substrate treatment apparatuses, there is usually a direct, laminar contact between the substrate carrier and the heating and/or cooling device, which can, for example, be a heating panel. In reality however, this laminar contact never ideally covers the entire surface, but because of irregularities within the surfaces of the substrate carrier and the heating panel in reality, results in a usually not precisely determinable, uneven support instead of a laminar one. As a result, the heating of the substrate carrier and thereby that of the overlying substrate, in case of a heating device, often concentrates on individual areas. This leads to an inhomogeneous, uneven heat distribution within the substrate carrier whereby distortions and tensions can form in the substrate carrier, so that it can deform itself. In addition, an uneven heat distribution within the substrate carrier leads to an uneven tempering of the at least one substrate provided on the substrate carrier front side.

Therefore, the object of the present invention is to propose a substrate treatment apparatus, which allows a heat distribution as evenly as possible within the substrate carrier.

The object is solved according to the invention by providing at least one spacer element on the substrate carrier back side and/or on one surface of the tempering device facing the substrate carrier in order to form a distance between the substrate carrier and the tempering device.

Therefore, according to the invention, at least one spacer element, that means a spacer, is provided between the substrate carrier and the tempering device, thus a direct contact between the substrate carrier and the tempering device is avoided. With this, punctual hot spots by shock heating, so called hotspots, are avoided within the substrate carrier. Inhomogeneities of a distance between the substrate carrier and the tempering device, which can be caused for example by machining tolerances, can be compensated by means of the at least one spacer element. A pattern of several spacer elements can for example be provided, which can compensate inhomogeneities exactly in the positions in which they occur. Through this, an even distance as homogenous as possible is established between the substrate carrier and the tempering device. Furthermore, a sum of a machining tolerance in the thickness direction of the substrate carrier, a thickness tolerance of the at least one spacer element and a montage tolerance of the at least one spacer element to the substrate carrier and/or the tempering device in thickness direction of the substrate carrier with regard to a thickness of the spacer element is relatively small. Preferably this sum amounts to less than 10%, particularly preferable less than 5% of the thickness of the spacer element. Thus, a heating behavior of the substrate carrier, in contrast to the state of the art, is no longer significantly affected by the said local tolerances of the substrate carrier and the spacer element, but the heating behavior is specifically adjustable by the thickness of the at least one spacer element.

A heat transfer between the tempering device and the substrate carrier can therefore, depending on the surrounding medium, essentially happen by convection or thermal radiation, to a certain extent also by heat conduction by the at least one spacer element. This guarantees an even heat input into the substrate carrier, whereby a homogeneous heat distribution within the substrate carrier can be achieved. Thus, distortions of the substrate carrier and an uneven tempering of the substrates placed on the substrate carrier can be avoided.

Furthermore, the heat transfer between the substrate carrier and the tempering device is throttled. Hence, in case of a heating process, there is a delayed heating of the substrate carrier, especially when placing a substrate carrier on a heating plate, a thermal shock is avoided by the spacer elements.

The spacer element according to the invention can comprise several geometrics. The spacer element can for example be formed in a cross section as a circle, circular ring, polygon or a polygon that is hollow inside. Furthermore, the spacer element can comprise recesses and/or through holes so that the spacer element is present on as few positions as possible between the substrate carrier and the tempering device and does not influence the heat transfer between the tempering device and the substrate carrier more than necessary. Preferably, the at least one spacer element comprises a width and/or length between 1 mm and 50 mm, preferably between 5 mm and 35 mm, particularly preferable between 15 mm and 25 mm in a direction of extension parallel to the substrate carrier back side. The width and/or length thereby relate to a continuous area of the spacer element, thus can be limited particularly by gaps in the spacer element or by curved edges.

The at least one spacer element can be arranged both on the substrate carrier back side as well as on the side of the tempering device facing the substrate carrier. The at least one spacer element can for example be included in the surface of the substrate carrier back side and/or in the surface of the side of the tempering device facing the substrate carrier, that means in form of a one-piece embodiment. Alternatively, the at least one spacer element can be bolted to the substrate carrier back side and/or the side of the tempering device facing the substrate carrier or can be otherwise tightly linked with one of the said surfaces. It is advantageous to form the connection between substrate carrier and spacer element(s) as detachable, whereby the at least one spacer element is interchangeable. An embodiment, in which the at least one spacer element is applied freely movable on the substrate carrier back side and/or on the surface of the side of the tempering device facing the substrate carrier, is also possible. One or several spacer pad(s) can for example be applied as (a) spacer element(s).

In a particularly preferred embodiment of the substrate treatment apparatus according to the invention, a multitude of the spacer elements is provided to form the distance between the substrate carrier and the tempering device. Thus, many small spacer elements are present between the substrate carrier and the tempering device, whereby the distance between the substrate carrier and the tempering device can, particularly in an outer area of the substrate carrier, be kept as large as in a centered area of the substrate carrier. Preferably, the height of the spacer elements, with which they protrude from the substrate carrier back side and/or the side of the tempering device facing the substrate carrier, is even; however, it can also have varying heights in order to balance inhomogeneities. By using a multitude of spacer elements, a thermal connection of the substrate carrier to the tempering device can be formed particularly even.

In an advantageous embodiment of the substrate treatment apparatus according to the invention, it is provided that the material of the at least one spacer element comprises a lower thermal conductivity than the material of the substrate carrier. Thus, the heat transfer between the tempering device and the substrate carrier through the at least one spacer element can be kept low and thus a selective heating of the substrate carrier and/or the substrate can be largely prevented. The heating of the substrate carrier in this case happens when the treatment of the substrate for example takes place under a gas atmosphere, primarily via a gas cushion, present between the tempering device and the substrate carrier. As a result, the heat transfer between the tempering device and the substrate carrier can be carried out by convection, which leads to an even heat distribution.

The spacer element can for example be formed from at least one electrically insulating material and/or be coated with at least one electrically insulating material. Electrically insulating materials are for the most part characterized by a low thermal conductivity. In this case, ceramic, glass and/or a synthetic material such as polyetheretherketone, teflon, a polyimide, and/or silicone, can be considered as a material for the spacer element. In the present invention it is generally also possible to form the at least one spacer element at least partially from aluminum, another metallic material or carbon.

The spacer element can preferably be formed as a braid or in sponge-like fashion, in order to carry out a low heat conduction between the tempering device and the substrate carrier. Alternatively, the spacer element or parts of it can be formed as a net, matrix and/or mat. The spacer element can be formed as covering the entire surface or individual sections between the tempering device and the substrate carrier. The use of a mat made of glass wool or silicone as a spacer element is for example possible. Such mats are usually flexible and/or compressible, thus in homogeneities in the distance between the substrate carrier and the tempering device can be completely compensated by a compressibility of the spacer element.

According to a preferred development of the substrate treatment apparatus according to the invention, the at least one spacer element projects the substrate carrier and/or the tempering device with a height between 0.1 mm and 1 mm, particularly preferable between 0.2 mm and 0.5 mm, especially between 0.3 mm and 0.4 mm. Thus, a sufficient and yet minimal distance between the tempering device and the substrate carrier is formed, so that the heat transfer in case of convection in a gas atmosphere takes place effectively and evenly. At the same time this distance leads, for example in a vacuum, to a holding of the temperature of the substrate carrier between different tempering devices, since a heat loss due to heat conduction is minimized and only a small heat loss can arise due to heat radiation.

In an advantageous embodiment of the substrate treatment apparatus according to the invention, the at least one spacer element comprises a variable height. The spacer element thus can for example be formed retractable and extendable in telescope-like fashion. Furthermore, the spacer element can be extended and/or height-adjusted from the tempering device and/or the substrate carrier back side and/or it can be fixed. The tempering device can for example comprise at least one hole or a drill hole, from which the spacer element can be extended and in which the spacer element can be lowered. With this, it is possible to at first apply the substrate carrier by the at least one spacer element at a far distance from the tempering device, for example with a distance of 1 mm, whereby a restricted tempering of the substrate carrier takes place in the first instance. Subsequently, the height of the at least one spacer element can be reduced, for example to approximately 0.3 mm, whereby the heat transfer between the tempering device and the substrate carrier takes place more effectively due to the shorter distance after that. Thus, a shock tempering is initially prevented and an effective heat transfer subsequently ensured.

Furthermore, it is advantageous if the substrate carrier is formed from at least one electrically conductive material and/or is coated with at least one electrically conductive material. Due to the mostly good thermal conductivity of electrically conductive material, the temperature of the tempering device can hereby be advantageously transferred to the substrate carrier. Furthermore, the electrical conductivity of the substrate carrier supports a homogeneous heat distribution within the substrate carrier, whereby potentially accruing hot spots in the substrate carrier can thermally balance themselves out; thus tensions and deformations of the substrate carrier can be avoided.

In addition, the substrate carrier in form of an electric conductor can be used for example as an electrode in the substrate treatment apparatus. This is particularly advantageous, if the at least one substrate to be treated is supposed to be adjusted to a specific electric potential. As a material, for example a metal or an alloy, particularly aluminum, titanium or an alloy of these metals, can be considered.

It may be advisable to choose the thickness of the substrate carrier between the substrate carrier front side and the substrate carrier back side as high as possible, in order to avoid a doming of the substrate carrier due to temperature inhomogeneities. On the one hand, the stiffness of the substrate carrier is thus increased, by which the substrate carrier can resist thermally induced tension better than with a lower thickness. On the other hand, the heat distribution in the substrate carrier is thereby improved and accelerated, which also counteracts a doming of the substrate carrier. The thickness of the substrate carrier should however not exceed a maximum thickness, since an increasing thickness of the substrate carrier negatively affects a dynamic of a heating-up and/or cooling process on the substrate carrier, since the thermal mass of the substrate carrier also increases with an increasing thickness. By using at least one spacer element between the substrate carrier and the tempering device, temperature inhomogeneities and thereby induced mechanical tensions, can be reduced and the thickness, and thus the mass and the thermal mass of the substrate carrier, can be kept at a minimum. The thickness of the substrate carrier thus interacts with the height of the spacer element; the higher the spacer element is, the lesser the thickness of the substrate carrier can be calculated. The minimized mass of the substrate carrier furthermore renders it possible to carry out a possible transport mechanism for transporting the substrate carrier on a small scale.

It has proven to be advantageous, if the substrate carrier comprises a thickness between 8 mm and 21 mm, preferably between 10 mm and 15 mm, particularly preferable between 11 mm and 13 mm between the substrate carrier front side and the substrate carrier back side. A width of the substrate carrier between 120 cm and 200 cm thus results in an aspect ratio of the thickness and the width of the substrate carrier of about 0.4% to 1.8%. With regard to substrate carriers of different lengths and widths, other advantageous thicknesses of the substrate carrier can arise.

In a particularly preferred embodiment of the substrate treatment apparatus according to the invention, the substrate carrier back side comprises a surface modification and/or a surface coating, wherein the surface modification and/or the surface coating absorbs more heat radiation than a basic material of the substrate carrier. This is particularly advantageous, if the heat transfer between the tempering device and the substrate carrier takes place mainly by heat radiation. If the substrate carrier or its surface is formed from a metal, for example aluminum, or a metal alloy, a majority of the heat radiation is reflected and an effective heat transfer between the tempering device and the substrate carrier does not happen. If the surface of substrate carrier back side is however functionalized in such a way that the heat radiation can be absorbed well, an effective heat transfer by heat radiation is possible, which is particularly of importance for processes in the vacuum.

Alternatively, it is also possible to provide the substrate carrier with a surface coating and/or a surface modification, which emits less heat radiation than a basic material of the substrate carrier. Through this, heat losses of the substrate carrier due to heat radiation can be minimized. It has for example proven to be advantageous, to form the substrate carrier front side as a polished aluminum surface, which comprises an emission degree relative to a black radiator or an absorption level of less than 0.2, while the substrate carrier back side can be an aluminum surface coated black, in a special case an anodized aluminum surface. Thus, the substrate carrier back side can comprise an emission degree or an absorption level of significantly more than 0.5, particularly preferred of more than 0.9. Thus the substrate carrier back side can effectively absorb the heat radiation emitted by the tempering device, while the substrate carrier front side emits as little heat radiation as possible.

Preferably, at least one receptacle module for including running rails is provided on the substrate carrier. Thus, the substrate carrier is slideable and/or moveable in at least one direction within the substrate treatment apparatus. This, for example, enables a continuous mode of operation of the substrate treatment apparatus, by continuously moving the substrate carrier with the substrates to be treated or processed through a substrate treatment chamber. The receptacle module is thereby arranged outside a substrate contact area, which means at the substrate carrier back side and/or at least at one side of the substrate carrier. Furthermore, receptacle modules can be provided on different positions, for example can receptacle modules be provided on at least one lateral outer area of the substrate carrier and/or in a central area at the substrate carrier back side.

It has proven to be particularly advantageous, if the at least one receptacle module is linked to the substrate carrier by at least one connecting element, wherein the connecting element comprises a smaller cross section and/or a greater length than the receptacle module in one connecting direction between the substrate carrier and the receptacle module. By choosing a connecting module with a small cross section in one connecting direction, in particular the heat transfer by heat conduction between the substrate carrier and the receptacle module is lessened geometrically. Thus, the formation of a heat sink at a affixing location of the at least one receptacle module can be minimized, which in turn prevents an uneven heat distribution in the substrate carrier.

In a likewise appropriate embodiment of the substrate treatment apparatus according to the invention, the at least one receptacle module and/or the connecting element is formed from a material or a material compound, which comprises a lower thermal conductivity than the material of the substrate carrier. By this, the heat transfer between the substrate carrier and the receptacle module is effectively reduced as well, which results in a heat distribution within the substrate carrier as evenly as possible. Thus, for the substrate carrier and the at least one receptacle module and/or the at least one connecting element, different materials are provided, whereby different thermal expansions or contractions of the substrate carrier and the at least one receptacle module and/or the at least one connecting elements can take place during a cooling or heating. Reasons for this are both the different temperatures of the substrate carrier, the receptacle module and the connecting element as well as different thermal expansion coefficients with different chosen materials of the substrate carrier, the receptacle module and the connecting element. Therefore, is has proven to be advantageous to mostly decouple the receptacle module mechanically from the substrate carrier. That means that the connecting element(s) placed between the substrate carrier and the receptacle module balance(s) the different thermal expansions of the substrate carrier, the connecting element itself and the receptacle module with one other. Is the at least one receptacle module for example formed in shape of running rails, the substrate carrier can be decoupled from the running rails by means of at least one movable connecting element.

Advantageous embodiments of the present invention, their structure, function and advantages are exemplified below by means of figures, wherein

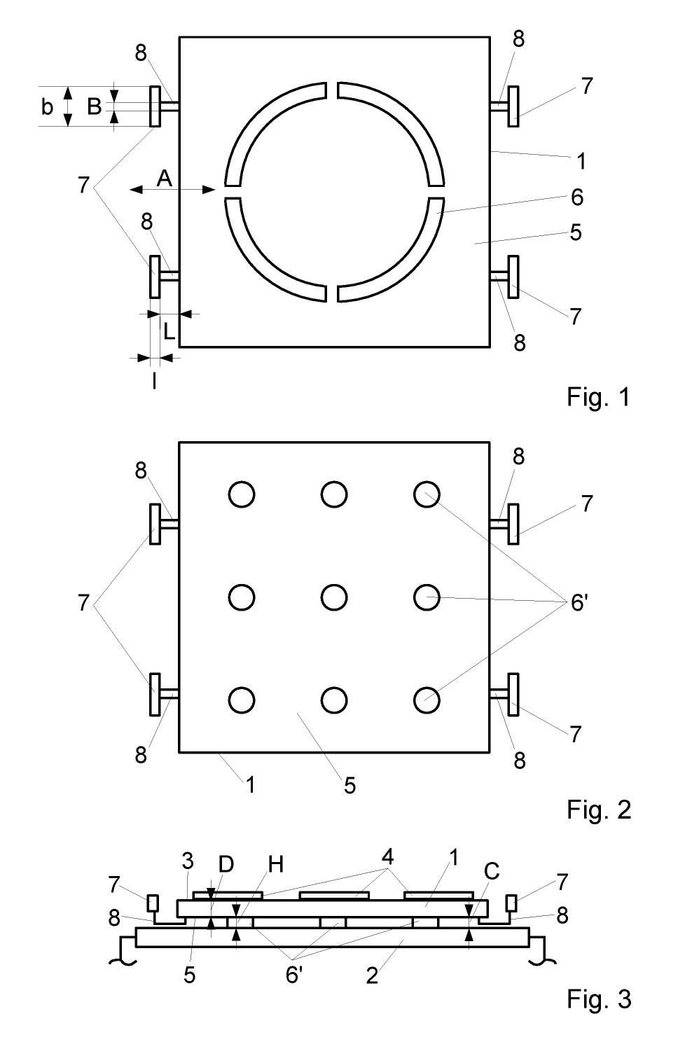

FIG. 1 schematically shows a substrate carrier according to an embodiment of a substrate treatment apparatus according to the invention with a single spacer element provided on the substrate carrier back side in a top-down view;

FIG. 2 schematically shows a substrate carrier in another embodiment of the substrate carrier according to the invention with a multitude of spacer elements provided on the substrate carrier back side in a top-down view; and

FIG. 3 schematically shows in a side-view an embodiment of the substrate treatment apparatus according to the invention with a substrate carrier and a tempering device and, arranged in between, spacer elements.

In FIG. 1, a schematic top-down view on a substrate carrier back side 5 of a substrate carrier 1 of an embodiment of the substrate treatment apparatus, is shown. According to this embodiment, exactly one spacer element 6 is provided on the substrate carrier back side 5, which in the shown example is formed in the cross section as a circular ring with four gaps. The spacer element 6 as present comprises an outer diameter, which equals about two-thirds of a side length of the substrate carrier 1. Preferably, the difference of the outer diameter and one inner diameter of the spacer element 6, which forms the width of the spacer element 6, in an area between 1 mm and 30 mm, particularly preferable between 10 mm and 25 mm.

As indicated in FIG. 1, the spacer element 6 can also comprise recesses and/or gaps. The spacer element 6 can comprise a different thermal expansion than the tempering device 2 or the substrate carrier 1. Due to the gaps, as well as the low width of the spacer element(s) 6, it is avoided, that deformations ensue because of the different thermal expansions. Furthermore, instead of the one spacer element 6, several spacer elements 6, in shape of a circular ring or a circular arc, can be arranged concentrically to one another on the substrate carrier back side 5. Thus, the spacer element(s) 6 can form an even distance C between the substrate carrier 1 and a, in FIG. 1 not depicted, tempering device 2, whereby an even temperature distribution in the substrate carrier 1 is enabled. In addition, a delayed tempering of the substrate carrier 1 ensues due to the spacer element(s), the heat transfer between the tempering device 2 and the substrate carrier 1 is thus throttled by the spacer element(s).

In the embodiment shown in FIG. 1, two receptacle modules 7 are arranged per side on two opposing sides of the substrate carrier 1, each of which are linked via a connecting element 8 with the substrate carrier 1. Alternatively, the use of more than two receptacle modules 7 along the length of the substrate carrier 1 is possible, in order to avoid a deflection of the substrate carrier 1, for example eight to ten receptacle modules 7 along the length of the substrate carrier 1 can be arranged. The connecting elements 8 comprise a smaller cross section B in the connection direction A between the substrate carrier 1 and the respective receptacle module 7, than the receptacle module 7 with the cross section b, thus can be formed for example rod- or bar-shaped. Furthermore, the length L of the connecting elements 8 is in the connection direction A greater than the length I of the corresponding receptacle modules 7 in the shown example. Due to this geometry of the connecting elements 8, the heat transfer from the substrate carrier 1 to the receptacle modules 7 is effectively reduced. Running rails or other transport mechanisms can engage with the receptacle modules 7, in order for the substrate carrier 1 to be moved for example through a substrate processing chamber.

In FIG. 2, another embodiment of the substrate treatment apparatus according to the invention in a top-down view on the substrate carrier back side 5 of the substrate carrier 1, is shown. For forming an even distance C between the substrate carrier 1 and a, in this figure not depicted, tempering device 2, a multitude of the spacer elements 6′ is arranged on the substrate carrier back side 5. The spacer elements 6′ here each comprise a circular cross section. Alternatively, other cross section geometries for the spacer elements 6′ are conceivable, for example circular, rectangular, triangular, octagonal or polygonal in any other way, oval or else comprising through openings/recesses. In addition, the same characteristics and functions as explained in FIG. 1 are provided for the receptacle modules 7 and the connecting elements 8.

The embodiment according to FIG. 2 has the advantage over the first embodiment according to FIG. 1, that an even distance C between the substrate carrier 1 and the tempering device 2 can also be formed in a peripheral area as well as a central area. According to the embodiment in accordance with FIG. 1, it is conceivable that the substrate carrier 1 deflects in said areas removed by the spacer element 6, towards the tempering device 2, so that the distance C between the tempering device and the substrate carrier 1 is not the same in all positions. This is avoided in the embodiment according to FIG. 2 by arranging the spacer elements 6′ evenly distributed across the substrate carrier back side 5, whereby also in the peripheral areas and the central area of the substrate carrier 1, an even distance C to the tempering device 2 can be formed.

Alternatively to the embodiments of the FIGS. 1 and 2 it is also conceivable without further ado and therefore not specifically depicted graphically, that the spacer elements 6, 6′ are arranged at a side of the tempering device 2 facing the substrate carrier 1, instead at the substrate carrier back side 5.

In FIG. 3, a side-view on the second embodiment according to FIG. 2 is shown. Between the tempering device 2 and the substrate carrier back side 5 of the substrate carrier 1, several spacer elements 6′ are arranged evenly spread, which comprise a height H. Due to this, an even distance C is formed between the tempering device 2 and the substrate carrier 1. The substrate carrier 1 comprises a thickness D in an area between 8 mm and 21 mm, preferably between 10 mm and 15 mm, particularly preferable between 11 mm and 13 mm, which leads to a sufficient stiffness of the substrate carrier 1, so that it does not bend. A greater thickness D of the substrate carrier 1, that is larger than 21 mm, is disadvantageous for a swift tempering of the substrate 4, since therefore a lot of material of the substrate carrier 1 needs to be tempered. For certain applications, a thickness D of the substrate carrier of more than 21 mm can also be advantageous, since the substrate carrier 1 thus can keep a set temperature, even after the tempering is turned off, for a longer time than a thin substrate carrier 1 with a thickness D between 8 mm and 21 mm, particularly with a thickness D of the substrate carrier 1 of less than 15 mm. A thickness D of the substrate carrier 1 of more than 21 mm can also be advantageous with a substrate carrier 1 with a length and/or width of more than 200 cm.

On one substrate carrier front side 3 of the substrate carrier 1, several substrates 4 are arranged. The substrates 4 shall be in a thermal balance with the substrate carrier 1, so that the substrates 4 can be heated and/or cooled indirectly by the tempering device 2. Thus, the substrates 4 can be adjusted to a desired temperature in a substrate treatment process. As substrate(s) can be applied, for example, semiconductor substrates, such as silicon wafers, on the substrate carrier 1.

From the substrate carrier back side 5, the connecting elements 8 extend laterally to the receptacle modules 7 and link them to the substrate carrier 1. Alternatively it is also conceivable that the connecting elements 8 are arranged lateral at the substrate carrier 1 or another area provided outside a substrate contact area of the substrate carrier 1. In the embodiment shown in FIG. 3, the connecting elements 8 comprise two deflections of in each case 90° between the substrate carrier 1 and the respective receptacle module 7. As a result, the connecting elements 8 comprise a greater length L than would be possible with a direct connection between the substrate carrier 1 and the respective receptacle module 7 along the connecting direction A. Due to an increasing length L of the connecting elements 8, the thermal conductivity is reduced by the connecting elements 8, whereby the heat transfer between the substrate carrier 1 and the receptacle modules 7 is minimized. Thus, a formation of heat sinks is avoided in the substrate carrier 1 at the positions of the connecting elements 8.

1-11. (canceled)

12. A substrate treatment apparatus for treating substrates, the substrate treatment apparatus comprising:
a plate-shaped substrate carrier having a substrate carrier front side for carrying at least one planar substrate and a substrate carrier back side;
at least one plate-shaped tempering device arranged in parallel to said substrate carrier and facing towards said substrate carrier back side;
at least one spacer element defining a spacing distance between said substrate carrier and said tempering device; and
at least one receptacle module for receiving running rails mounted to said substrate carrier.

13. The substrate treatment apparatus according to claim 12, wherein said at least one spacer element is disposed on said substrate carrier back side and/or on a surface of said tempering device facing the substrate carrier.

14. The substrate treatment apparatus according to claim 12, wherein said at least one spacer element is one of a multitude of the spacer elements for forming the distance between said substrate carrier and said tempering device.

15. The substrate treatment apparatus according to claim 12, wherein a material of said at least one spacer element has a lower thermal conductivity than a material of said substrate carrier.

16. The substrate treatment apparatus according to claim 12, wherein said at least one spacer element projects from said substrate carrier and/or from said tempering device by a height between 0.1 mm and 1 mm.

17. The substrate treatment apparatus according to claim 12, wherein said at least one spacer element is configured with a variable height.

18. The substrate treatment apparatus according to claim 12, wherein said substrate carrier is formed of an electrically conductive material.

19. The substrate treatment apparatus according to claim 12, wherein said substrate carrier is coated with at least one electrically conductive material.

20. The substrate treatment apparatus according to claim 12, wherein said substrate carrier has a thickness between said substrate carrier front side and said substrate carrier back side of between 8 mm and 21 mm.

21. The substrate treatment apparatus according to claim 12, wherein said substrate carrier back side is formed with a surface modification and/or a surface coating configured to absorb more thermal radiation than a basic material of said substrate carrier.

22. The substrate treatment apparatus according to claim 12, which comprises at least one connecting element connecting said at least one receptacle module to said substrate carrier, said connecting element having a smaller cross section and/or a greater length than a receptacle module in one connecting direction between said substrate carrier and said receptacle module.

23. The substrate treatment apparatus according to claim 22, wherein said at least one receptacle module and/or said connecting element are formed from a material or a material compound having a lower thermal conductivity than a material of said substrate carrier.
